(19) United States
(12) Patent Application Publication
(10) Pub. No.: US 2025/0318057 A1
(43) Pub. Date: Oct. 9, 2025

(54) ELECTRONIC CONTROL APPARATUS AND BRAKE APPARATUS

(71) Applicant: HL MANDO CORPORATION, Pyeongtaek-si (KR)

(72) Inventor: Minseong KIM, Pyeongtaek-si (KR)

(73) Assignee: HL MANDO CORPORATION, Pyeongtaek-si (KR)

(21) Appl. No.: 19/020,057

(22) Filed: Jan. 14, 2025

(30) Foreign Application Priority Data
Apr. 4, 2024 (KR) 10-2024-0046282

(51) Int. Cl. H05K 5/00; B60T 8/171; B60T 8/172; H05K 1/14; H05K 7/14

(52) U.S. Cl. CPC H05K 5/0069; B60T 8/171; B60T 8/172; H05K 1/14; H05K 7/1427; B60T 2220/04; B60T 2270/402

(57) ABSTRACT

An electronic control apparatus may include: a first housing that forms a first accommodating space; a second housing that forms a second accommodating space different from the first accommodating space; a conductive first pin that penetrates through the first housing and is fixed to the first housing; a conductive second pin that penetrates through the second housing and is fixed to the second housing; a conductive connection member that electrically connects the second pin to the first pin; a first printed circuit board that is provided in the first accommodating space, has a first through hole into which the first pin is inserted, and is electrically connected to the first pin; and a second printed circuit board that is provided in the second accommodating space, has a second through hole into which the second pin is inserted, and is electrically connected to the second pin.

### CROSS-REFERENCE TO RELATED APPLICATIONS

This application claims the priority of Korean Patent Application No. 10-2024-0046282 filed on Apr. 4, 2024, in the Korean Intellectual Property Office, the disclosure of which is incorporated by reference herein in its entirety.

### BACKGROUND

### Field

The present disclosure relates to an electronic control apparatus and brake apparatus that secure redundancy.

### Description of the Related Art

A vehicle is a transportation means that transports people, cargo, etc., and includes various apparatuses such as a driving apparatus, a steering apparatus, and a brake apparatus.

Recently, apparatuses installed in vehicles are becoming electronic. For example, a vehicle may be controlled electrically without a mechanical or fluid connection between a pedal/steering wheel and the brake apparatus/steering apparatus, which may be operated by a driver, such as brake-by-wire, steering-by-wire, etc. In addition, autonomous driving in which a vehicle is controlled on its own without direct manipulation by a driver through the pedal/steering wheel is being implemented.

In this way, when a vehicle is controlled only by electrical signals, an there is a risk that a fail of electrical/electronic system or a fail of a power supply may lead to a fatal accident.

Recently, securing the redundancy in the vehicle in preparation for the fail of the electrical/electronic system or the fail of the power supply has emerged as a major issue.

### SUMMARY

The present disclosure is directed to provide an electronic control apparatus for a vehicle that secures redundancy.

The present disclosure is directed to provide a brake apparatus for a vehicle that secures redundancy.

An electronic control apparatus according to an aspect of the present disclosure may include: a first housing that forms a first accommodating space; a second housing that forms a second accommodating space different from the first accommodating space; a conductive first pin that penetrates through the first housing and is fixed to the first housing; a conductive second pin that penetrates through the second housing and is fixed to the second housing; a first printed circuit board that is provided in the first accommodating space, has a first through hole into which the first pin is inserted, and is electrically connected to the first pin; a second printed circuit board that is provided in the second accommodating space, has a second through hole into which the second pin is inserted, and is electrically connected to the second pin; and a conductive connection member that electrically connects the second pin to the first pin.

The first housing may be provided on the second housing. Further, at least a portion of the first housing may overlap the second housing.

The first pin may be insert-molded into the first housing. Further, the second pin may be insert-molded into the second housing.

The first pin may protrude to the first accommodating space through the first housing and may be connected to the first printed circuit board in accommodated the first accommodating space. Further, the second pin may protrude to the second accommodating space through the second housing and may be connected to the second printed circuit board accommodated in the second accommodating space.

The first pin may include a first pin body fixed to the first housing, and a first pin head provided on one side of the first pin body and inserted into the first through hole of the first printed circuit board. Further, the second pin may include a second pin body fixed to the second housing, and a second pin head provided on one side of the second pin body and inserted into the second through hole of the second printed circuit board.

The first pin may include a first connection head provided at one end of the first pin body and in contact with the connection member. Further, the second pin may include a second connection head provided at one end of the second pin body and in contact with the connection member.

The first connection head may have at least one of a rugby ball shape, a fork shape, and an arrowhead shape.

The first connection head may be provided in the first accommodating space. Further, the second connection head may be provided outside the second accommodating space.

The connection member may include at least one of a cylindrical spring, an hourglass-shaped spring, an offset spring, and a zigzag-shaped leaf spring.

The electronic control apparatus may further include a potting member that surrounds the second pin penetrating through the second housing.

The second housing may include a coupling guide on which the connection member is seated.

The first pin may be electrically connected to at least one of an external power supply, a pedal sensor, a motor, a valve, and a pressure sensor.

The electronic control apparatus may further include a first processor mounted on the first printed circuit board, and a second processor mounted on the second printed circuit board. Further, the first processor may be electrically connected to the second processor through the first pin, the connection member, and the second pin.

The first processor may output a control signal. Further, the second processor may output a control signal based on a failure of the first processor.

A brake apparatus according to another aspect of the present disclosure may include: a sensor; a motor; a valve; a pressure sensor; and an electronic control apparatus that controls at least one of the motor and the valve based on an output of the pedal sensor and the pressure sensor. The electronic control apparatus may include: a first housing that forms a first accommodating space; a second housing that forms a second accommodating space different from the first accommodating space; a plurality of first pins that penetrates through the first housing, is fixed to the first housing, and is electrically connected to the pedal sensor, the motor, the valve, and the pressure sensor, respectively; a plurality of second pins that penetrates through the second housing and is fixed to the second housing; a first printed circuit board that is provided in the first accommodating space, has a plurality of first through holes into which each of the plurality of first pins is inserted, and is electrically connected to the plurality of first pins; and a second printed circuit board that is provided in the second accommodating space, has a plurality of second through holes into which each of the plurality of second pins is inserted, and is electrically connected to the plurality of second pins; and a plurality of connection members that electrically connects the plurality of second pins to the plurality of first pins, respectively.

The first housing may be provided on the second housing. Further, at least a portion of the first housing may overlap the second housing.

The plurality of first pins may be insert-molded into the first housing. Further, the plurality of second pins may be insert-molded into the second housing.

An electronic control apparatus according to still another aspect of the present disclosure may include: a first electronic control apparatus that includes a first housing including a plurality of first pins protruding to a first accommodating space and a first printed circuit board accommodated in the first accommodating space and electrically connected to the plurality of first pins; a second electronic control apparatus that includes a second housing including a plurality of second pins protruding to a second accommodating space and a second printed circuit board accommodated in the second accommodating space and electrically connected to the plurality of second pins; and a plurality of connection members that electrically connects the plurality of second pins to the plurality of first pins, respectively.

The first electronic control apparatus may be provided on the second electronic control apparatus. Further, at least a portion of the first electronic control apparatus may overlap the second electronic control apparatus.

The plurality of first pins may be insert-molded into the first housing. Further, the plurality of second pins may be insert-molded into the second housing.

The effects of the present disclosure are not limited to the aforementioned effects, and other effects, which are not mentioned above, will be apparently understood to a person having ordinary skill in the art from the following description.

The objects to be achieved by the present disclosure, the means for achieving the objects, and the effects of the present disclosure described above do not specify essential features of the claims, and, thus, the scope of the claims is not limited to the disclosure of the present disclosure.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 diagram illustrating a brake apparatus including an electronic control apparatus according to an exemplary embodiment;

FIG. 2 is a diagram illustrating appearances of first and second electronic control apparatuses and valves according to an exemplary embodiment;

FIG. 3 is a diagram illustrating side cross-sections of the first and second electronic control apparatuses according to an exemplary embodiment;

FIG. 4 is a diagram illustrating an exploded perspective view of the first electronic control apparatus and the valve according to an exemplary embodiment in one direction;

FIG. 5 is a diagram illustrating an exploded perspective view of the first electronic control apparatus and the valve according to an exemplary embodiment in another direction;

FIG. 6 is a diagram illustrating an exploded perspective view of the second electronic control apparatus according to an exemplary embodiment in one direction;

FIG. 7 is a diagram illustrating an exploded perspective view of the second electronic control apparatus according to an exemplary embodiment in another direction;

FIG. 8 is a diagram illustrating side cross-sections of the first and second electronic control apparatuses according to an exemplary embodiment;

FIGS. 9A, 9B, 9C, 9D, and 9E are diagrams illustrating an example of a conductive connection member connecting the first electronic control apparatus and the second electronic control apparatus according to an exemplary embodiment;

FIGS. 10A, 10B, 10C, 10D, and 10E are diagrams schematically illustrating an example of assembling the according to an exemplary electronic control apparatus embodiment;

FIG. 11 is a diagram illustrating an example of a first pin, a second pin, and a conductive connection member of the electronic control apparatus according to an exemplary embodiment;

FIG. 12 is a diagram illustrating an example of the first pin, the second pin, and the conductive connection member of the electronic control apparatus according to an exemplary embodiment;

FIG. 13 is a diagram illustrating an example of the first pin, the second pin, and the conductive connection member of the electronic control apparatus according to an exemplary embodiment;

FIG. 14 is a diagram illustrating an example of the first pin, the second pin, and the conductive connection member of the electronic control apparatus according to an exemplary embodiment;

FIG. 15 is a diagram illustrating an example of the first pin and the second pin of the electronic control apparatus according to an exemplary embodiment; and

FIG. 16 is a diagram conceptually illustrating the first and the second electronic control apparatuses according to an exemplary embodiment.

### DETAILED DESCRIPTION

The following detailed description is provided to assist the reader in gaining a comprehensive understanding of the methods, apparatuses, and/or systems described herein. Accordingly, various changes, modifications, and equivalents of the methods, apparatuses, and/or systems described herein will be suggested to those of ordinary skill in the art. The progression of processing operations described is an example; however, the sequence of and/or operations is not limited to that set forth herein and may be changed as is known in the art, with the exception of operations necessarily occurring in a particular order. In addition, respective descriptions of well-known functions and constructions may be omitted for increased clarity and conciseness.

Additionally, exemplary embodiments will now be described more fully hereinafter with reference to the accompanying drawings. The exemplary embodiments may, however, be embodied in many different forms and should not be construed as being limited to the embodiments set forth herein. These embodiments are provided so that this disclosure will be thorough and complete and will fully convey the exemplary embodiments to those of ordinary skill in the art. Like numerals denote like elements throughout.

It will be understood that, although the terms first, second, etc. may be used herein to describe various elements, these elements should not be limited by these terms. These terms are only used to distinguish one element from another. As used herein, the term “and/or,” includes any and all combinations of one or more of the associated listed items.

It will be understood that when an element is referred to as being “connected,” or “coupled,” to another element, it can be directly connected or coupled to the other element or intervening elements may be present. In contrast, when an element is referred to as being “directly connected,” or “directly coupled,” to another element, there are no intervening elements present.

The terminology used herein is for the purpose of describing particular embodiments only and is not intended to be limiting. As used herein, the singular forms “a,” “an,” and “the,” are intended to include the plural forms as well, unless the context clearly indicates otherwise.

The expression, “at least one of a, b, and c,” should be understood as including only a, only b, only c, both a and b, both a and c, both b and c, or all of a, b, and c.

Reference will now be made in detail to the exemplary embodiments of the present disclosure, examples of which are illustrated in the accompanying drawings, wherein like reference numerals refer to like elements throughout.

Hereinafter, the exemplary embodiment of the present disclosure will be described with reference to the accompanying drawings and exemplary embodiments as follows. Scales of components illustrated in the accompanying drawings are different from the real scales for the purpose of description, so that the scales are not limited to those illustrated in the drawings.

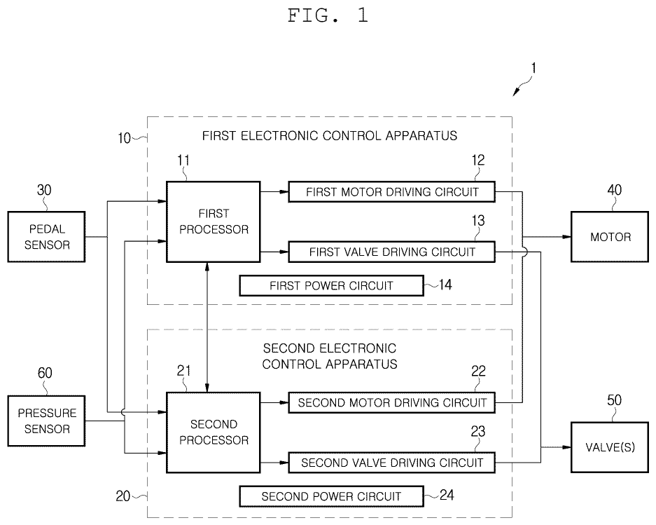

FIG. 1 is a diagram illustrating a brake apparatus including an electronic control apparatus according to an exemplary embodiment.

Electronic control apparatuses 10 and 20 installed in a brake apparatus 1 illustrated in FIG. 1 are only an example of the electronic control apparatus of the present disclosure. The electronic control apparatus of the present disclosure may apply to any electrical/electronic apparatus installed in a vehicle. The electronic control apparatuses 10 and 20 of the present disclosure may be, for example, an engine control module (ECU), a transmission control unit (TCU), an electronic control unit (ECU) of an electric power steering (EPS), a body control unit (BCU), or a vehicle control unit.

As illustrated in FIG. 1, the brake apparatus 1 may include a pedal sensor 30, a motor 40, a valve(s) 50, a pressure sensor 60, a first electronic control apparatus 10, and/or a second electronic control apparatus 20. The pedal sensor 30, the motor 40, the valve(s) 50, and the pressure sensor 60 illustrated in FIG. 1 do not correspond to essential components of the present disclosure, and the pedal sensor 30, the motor 40, the valve(s) 50, and the pressure sensor 60 may be omitted.

The brake apparatus 1 may provide pressure (hereinafter (referred to as ‘hydraulic pressure’) of a pressurized medium (e.g., brake oil, etc.) for braking a vehicle to a plurality of wheels installed in the vehicle, based on an output signal of the pedal sensor 30.

For example, the brake apparatus 1 may include a hydraulic pressure supply device that generates hydraulic pressure and a hydraulic pressure control device that controls the generated hydraulic pressure. The hydraulic pressure supply device may include, for example, a piston-cylinder pump or a rotary pump driven by the motor 40. The hydraulic pressure control device may include, for example, a flow path extending from the hydraulic pressure supply device to a wheel cylinder installed on a wheel of a vehicle and a valve(s) 50 that opens or closes the flow path.

The pedal sensor 30 may detect movement of a brake pedal, which indicates driver's braking intention, and output an electrical signal (e.g., a voltage signal or current signal) (hereinafter referred to as a ‘pedal signal’) corresponding to the movement of the brake. The brake pedal may move by a driver, and the pedal sensor 30 may detect the movement of the brake pedal by the driver. The pedal sensor 30 may output a pedal signal corresponding to a displacement of the brake pedal or a moving speed of the brake pedal to the first electronic control apparatus 10 and the second electronic control apparatus 20.

The motor 40 may provide power (torque) for generating the hydraulic pressure to a piston-cylinder pump or rotary pump. For example, the torque of the motor 40 is converted into translational motion force by a power conversion device (e.g., spindle-nut or pinion-rack, etc.), and the piston of the piston-cylinder pump may perform translational motion by the translational motion force. In addition, a rotor of the rotary pump may rotate by the torque of the motor 40.

The motor 40 may include, for example, a rotor and a stator, and the rotor or stator may include a plurality of coils that generates a rotating magnetic field. The motor 40 may be driven by a motor driving current supplied to a plurality of coils.

The valve(s) 50 may allow or block the hydraulic pressure that is generated by the hydraulic pressure supply device and provided to the wheel cylinder. Furthermore, the valve(s) 50 may modulate or regulate the hydraulic pressure that is generated by the hydraulic pressure supply device and provided to the wheel cylinder.

The valve(s) 50 may include, for example, an electrically controllable solenoid valve. The solenoid valve may include a coil that generates a magnetic field. The valve(s) 50 may be open (normally closed type valve) or closed (normally open type valve) by the valve driving current supplied to the coil.

The pressure sensor 60 may be provided on a flow path extending from the hydraulic pressure supply device to the wheel cylinder, and may measure the hydraulic pressure that is generated by the hydraulic pressure supply device and provided to the wheel cylinder. In addition, the pressure sensor 60 may output an electrical signal (e.g., a voltage signal or a current signal) (hereinafter referred to as a ‘pressure signal’) corresponding to the measured hydraulic pressure. The hydraulic pressure of the flow path may change by the operation of the motor 40 and/or the valve 50, and the pressure sensor 60 may measure the changing hydraulic pressure of the flow path.

The first electronic control apparatus 10 may control the motor 40 and/or valve(s) 50 based on the output signal of the pedal sensor 30 and/or the pressure sensor 60. For example, the first electronic control apparatus 10 may include a first motor driving circuit 12, a first valve driving circuit 13, a first power circuit 14, and a first processor 11. The first motor driving circuit 12 and the first valve driving circuit 13 illustrated in FIG. 1 do not correspond to essential components of the first electronic control apparatus 10 according to an exemplary embodiment, and the first motor driving circuit 12 and/or the first valve driving circuit 13 may be omitted.

The first motor driving circuit 12 may be connected to the coil constituting the motor 40 and control the motor driving current flowing through the coil.

The first motor driving circuit 12 may receive a control signal from the first processor 11 and control a motor driving current that drives the motor 40 in response to the control signal from the first processor 11. The first motor driving circuit 12 may control the motor driving current to increase the hydraulic pressure of the hydraulic pressure supply device in response to a pressure signal from the first processor 11. In addition, the first motor driving circuit 12 may control the motor driving current to decrease the hydraulic pressure of the hydraulic pressure supply device in response to a decompression signal from the first processor 11.

The first motor driving circuit 12 may include an inverter circuit or an H-bridge circuit that controls the motor driving current supplied to the motor 40. The inverter circuit or H-bridge circuit may include a plurality of transistors that is turned on or off in response to a control signal from the first processor 11.

The first valve driving circuit 13 may be connected to the coil constituting the valve 50 and control the valve driving current flowing through the coil.

The first valve driving circuit 13 may receive the control signal from the first processor 11 and control a valve driving current that drives the valve 50 in response to the control signal from the first processor 11. For example, the first valve driving circuit 13 may control the valve driving current to open the valve 50 in response to an opening signal from the first processor 11. In addition, the first valve driving circuit 13 may control the valve driving current to close the valve 50 in response to a closed signal from the first processor 11.

The first valve driving circuit 13 may include a switching circuit that controls the valve driving current supplied to the valve 50. The switching circuit may include a transistor that is turned on or off in response to the control signal from the first processor 11.

The first power circuit 14 may receive original power from an external power device and convert a voltage of the original power. The first power circuit 14 may provide voltage-converted power to the pedal sensor 30, the pressure sensor 60, the first motor driving circuit 12, the first valve driving circuit 13, and/or the first processor 11.

The first power circuit 14 may convert the original power into power of a plurality of different voltages. For example, the first power circuit 14 may convert the voltage of the original power into a first voltage suitable for the pedal sensor 30, the pressure sensor 60, and/or the first processor 11, and may also convert the voltage of the original power into a second voltage suitable for the first motor driving circuit 12 and/or the first valve driving circuit 13.

The first power circuit 14 may include, for example, at least one DC-DC converter or at least one regulator. The DC-DC converter may include at least one inductor and at least one capacitor. The regulator may include a breakdown diode.

The first processor 11 may receive a pedal signal of the pedal sensor 30 and a pressure signal of the pressure sensor 60, provide a first motor control signal to the first motor driving circuit 12, and provide a first valve control signal to the first valve driving circuit 13. For example, the first processor 11 may provide the first motor control signal and the first valve control signal to the first motor driving circuit 12 and the first valve driving circuit 13, respectively, to supply the hydraulic pressure to the wheel cylinder based on the pedal sensor 30 corresponding to the driver's braking initiation intention. In addition, the first processor 11 may provide the first motor control signal and the first valve control signal to the first motor driving circuit 12 and the first valve driving circuit 13, respectively, to recover the hydraulic pressure of the wheel cylinder based on the pedal sensor 30 corresponding to the driver's braking stop intention.

The second electronic control apparatus 20 may control the motor 40 and/or valve(s) 50 based on the output signal of the pedal sensor 30 and/or the pressure sensor 60. For example, the second electronic control apparatus 20 may include a second motor driving circuit 22, a second valve driving circuit 23, a second power circuit 24, and a second processor 21. The second motor driving circuit 22 and the second valve driving circuit 23 illustrated in FIG. 1 do not correspond to essential components of the second electronic control apparatus 20 according to an exemplary embodiment, and the second motor driving circuit 22 and/or the second valve driving circuit 23 may be omitted.

The configuration and function of the second electronic control apparatus 20 may be the same as those of the first electronic control apparatus 10. In other words, configurations and functions of the second motor driving circuit 22, the second valve driving circuit 23, the second power circuit 24, and the second processor 21 may be the same as those of the first motor driving circuit 12, the first valve driving circuit 13, the first power circuit 14, and the first processor 11, respectively.

The second electronic control apparatus 20 may operate auxiliary to the first electronic control apparatus 10. For example, the second electronic control apparatus 20 does not operate or does not output a control signal during the normal operation of the first electronic control apparatus 10, and may operate when the fail of the first electronic control apparatus 10 is detected. In other words, when the fail of at least one of the first motor driving circuit 12, the first valve driving circuit 13, the first power circuit 14, and the first processor 11 is detected, the second electronic control apparatus 20 may output the control signal.

The first electronic control apparatus 10 may operate auxiliary to the second electronic control apparatus 20. For example, the first electronic control apparatus 10 does not operate or does not output the control signal during the normal operation of the second electronic control apparatus 20, and may operate when the fail of the second electronic control apparatus 20 is detected. In other words, when the fail of at least one of the second motor driving circuit 22, the second valve driving circuit 23, the second power circuit 24, and the second processor 21 is detected, the first electronic control apparatus 10 may output the control signal.

The first processor 11 of the first electronic control apparatus 10 may be communicatively connected to the second processor 21 of the second electronic control apparatus 20. The first processor 11 may provide the operating state (e.g., normal operating state or fail state, etc.) of the first electronic control apparatus 10 to the second processor 21. In addition, the second processor 21 may provide the operating state of the second electronic control apparatus 20 to the first processor 11.

The first processor 11 may provide a periodic signal (e.g., a pulse signal, a sine wave signal, etc.) to the second processor 21 during the normal operation. In addition, the second processor 21 may provide the periodic signal (e.g., a pulse signal, a sine wave signal, etc.) to the first processor 11 during the normal operation.

As described above, the second electronic control apparatus 20 may provide redundancy to the first electronic control apparatus 10, and the first electronic control apparatus 10 may also provide redundancy to the second electronic control apparatus 20.

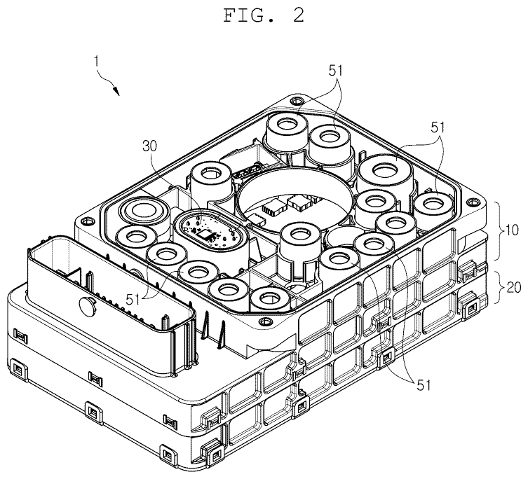

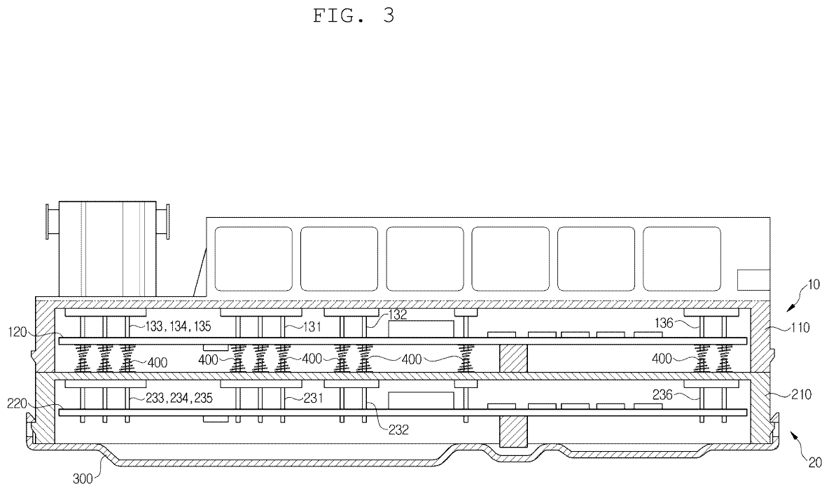

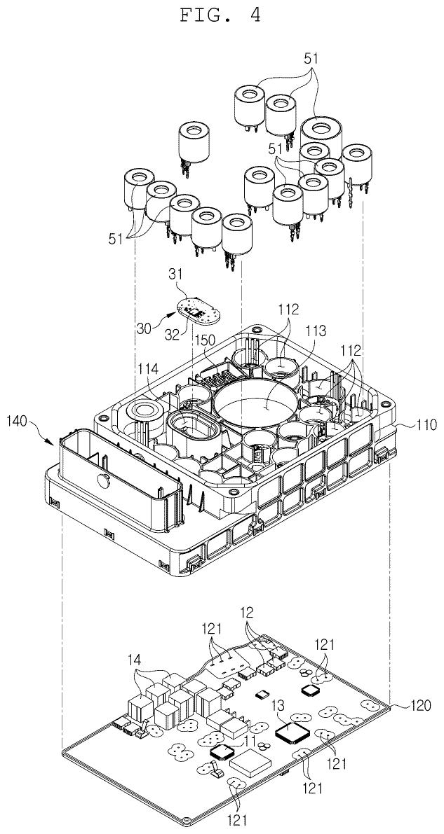

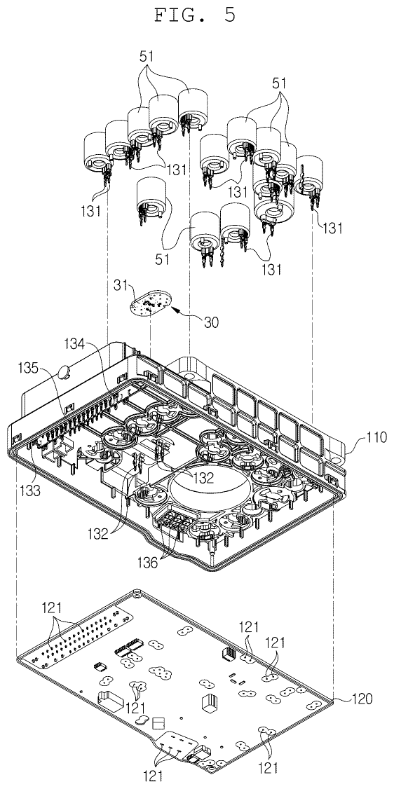

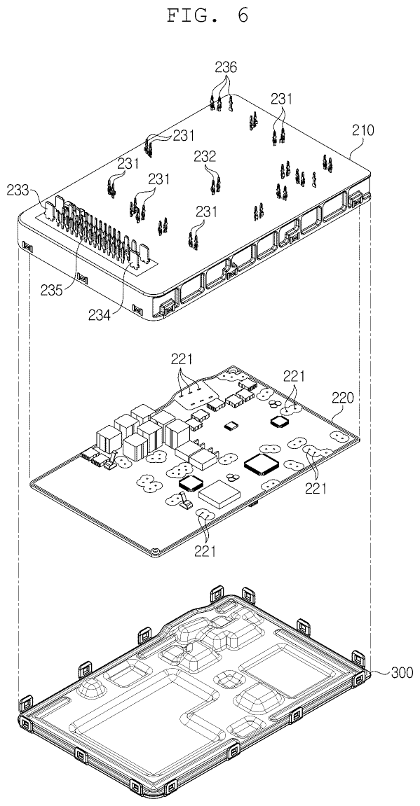

FIG. 2 is a diagram illustrating appearances of first and second electronic control apparatuses and valves according to an exemplary embodiment. FIG. 3 is a diagram illustrating side cross-sections of the first and second electronic control apparatuses according to an exemplary embodiment. FIG. 4 is a diagram illustrating an exploded perspective view of the first electronic control apparatus and the valve according to an exemplary embodiment in one direction. FIG. 5 is a diagram illustrating an exploded perspective view of the first electronic control apparatus and the valve according to an exemplary embodiment in another direction. FIG. 6 is a diagram illustrating an exploded perspective view of the second electronic control apparatus according to an exemplary embodiment in one direction. FIG. 7 is a diagram illustrating an exploded perspective view of the second electronic control apparatus according to an exemplary embodiment in another direction.

As illustrated in FIGS. 2 and 3, the brake apparatus 1 may include a plurality of valve coils 51, the pedal sensor 30, the first electronic control apparatus 10, and the second electronic control apparatus 20. The plurality of valve coils 51 and the pedal sensor 30 are not essential components of the brake apparatus 1, and the plurality of valve coils 51 and the pedal sensor 30 may be omitted.

FIGS. 4 and 5 illustrate the valve 50, the pedal sensor 30, and the first electronic control apparatus 10, and FIGS. 6 and 7 illustrate the second electronic control apparatus 20. The first electronic control apparatus 10 illustrated in FIGS. 4 and 5 and the second electronic control apparatus 20 illustrated in FIGS. 6 and 7 may integrally form the electronic control apparatus of the brake apparatus 1.

As illustrated in FIGS. 4 and 5, the first electronic control apparatus 10 may include a first housing 110, a first printed circuit board 120, and electrical and/or electronic components mounted thereon.

The first housing 110 forms an appearance of the first electronic control apparatus 10 and may be made of a non-conductive material. The first housing 110 may protect the first printed circuit board 120 and the electrical/electronic components mounted thereon from the outside. In particular, the first housing 110 may seal its internal space from the outside, thereby blocking external foreign substances such as moisture from flowing into the inside.

A first accommodating space accommodating the first printed circuit board 120 is formed on one surface of the first housing 110, and one side of the first accommodating space may be open. One open side of the first accommodating space may be closed by the second electronic control apparatus 20.

The plurality of valve coils 51 constituting the plurality of valves 50 may be provided outside the first accommodating space formed in the first housing 110. A plurality of first seating spaces 112 may be provided on the opposite surface (hereinafter referred to as the ‘other surface’) of one surface of the first housing 110 on which the first accommodating space is formed.

Each of the plurality of valve coils 51 may be seated in the plurality of first seating spaces 112 formed on the other surface of the first housing 110. A first valve pin 131 connected to the terminals of the plurality of valve coils 51 may penetrate from the other surface of the first housing 110 to one surface through a through hole formed in the first housing 110. In other words, the first valve pin 131 of the plurality of valve coils 51 may extend from the first seating space 112 of the first housing 110 to the first accommodating space of the first housing 110. In this way, the plurality of valve coils 51 may be electrically connected to the first electronic control apparatus 10 through the first valve pin 131 extending to the first accommodating space of the first housing 110.

A first hollow 113 may be formed in approximately a central portion of the first housing 110. A pump not illustrated in the drawing may be seated in the first hollow 113.

A second seating space 114 may be formed in approximately the central portion of the first housing 110. The pedal sensor 30 may be seated in the second seating space 114.

The pedal sensor 30 may include a sensor circuit board 31 and a sensor device 32 mounted on the sensor circuit board 31.

The sensor circuit board 31 is seated in the second seating space 114 and may be electrically or communicatively connected to the first electronic control apparatus 10 through the first pedal sensor pin 132.

The sensor circuit board 31 may be provided in the second seating space 114 of the housing 100, and the sensor device 32 may be exposed to the outside through the second seating space 114. The sensor device 32 may detect the position and/or movement of the brake pedal. For example, the brake pedal may be provided with a magnet that moves together with the brake pedal, and the sensor device 32 may include a hall sensor capable of detecting a magnetic field generated by the magnet.

The sensor circuit board 31 may be electrically connected to the first electronic control apparatus 10 through the first pedal sensor pin 132. The pedal signal of the sensor device 32 may be provided to the first processor 11 included in the first electronic control apparatus 10 through the first pedal sensor pin 132 of the sensor circuit board 31.

The first pedal sensor pin 132 may penetrate through the first housing 110 to be connected to the first electronic control apparatus 10. The first pedal sensor pin 132 may be made of an electrically conductive material, for example, metal, and may transmit the pedal signal of the pedal sensor 30 to the first electronic control apparatus 10.

The first pedal sensor pin 132 may be provided integrally with the first housing 110. For example, the first pedal sensor pin 132 may be fixed to the first housing 110 through an insert molding method.

A power connector 140 may be provided on one side of the first housing 110 to receive power from an external power supply and connect to a vehicle communication network. The power connector 140 may be exposed to the outside of the first housing 110.

The power connector 140 may further include a first power pin 133 and a first ground pin 134 for receiving power from an external power supply, and a first communication pin 135 for connecting to the vehicle communication network. The voltage of the original power may be applied between the first power pin 133 and the first ground pin 134. In addition, the current of the original power may flow in through the first power pin 133 and may flow out through the first ground pin 134. The first power pin 133 and the first ground pin 134 may be insulated by air.

The first power pin 133, the first ground pin 134, and the first communication pin 135 may penetrate through the first housing 110 to be connected to the first electronic control apparatus 10. In particular, the first power pin 133, the first ground pin 134, and the first communication pin 135 may be fixed to the first housing 110 through the insert molding method.

A motor connector 150 may be provided on one side of the first housing 110 to provide a motor driving current to the motor 40. The motor connector 150 may include a plurality of first motor pins 136 connected to a plurality of terminals of the motor 40. For example, when the motor 40 is a three-phase motor, the plurality of first motor pins 136 may include a first U-phase pin, a first V-phase pin, and a first W-phase pin.

The plurality of first motor pins 136 may penetrate through the first 110 to be connected to the first electronic control apparatus 10. The plurality of first motor pins 136 may be fixed to the first housing 110 through the insert molding method.

The first electronic control apparatus 10 may further include a first printed circuit board 120 provided in the first accommodating space of the first housing 110, and electrical and/or electronic components mounted on the first printed circuit board 120 to implement the functions of the first electronic control apparatus 10.

A first pedal sensor pin 132, a first power pin 133, a first ground pin 134, a first communication pin 135, and a plurality of first motor pins 136 that are fixed to the first housing 110 may be inserted into the first printed circuit board 120. In addition, the first valve pins 131 of the plurality of valve coils 51 may also be inserted into the first printed circuit board 120.

A plurality of first through holes 121 into which the first pedal sensor pin 132, the first power pin 133, the first ground pin 134, the first communication pin 135, the plurality of first motor pins 136 and/or first valve pins 131 are inserted may be formed on the first printed circuit board 120. In addition, the first printed circuit board 120 may be electrically connected to the first pedal sensor pin 132, the first power pin 133, the first ground pin 134, the first communication pin 135, and the plurality of first motor pins 136 and/or the first valve pin 131.

The first electronic control apparatus 10 includes the first power circuit 14. A capacitor and an inductor constituting the first power circuit 14 may be mounted on the first printed circuit board 120. The capacitor and inductor may constitute the DC-DC converter that converts the voltage of the original power.

The first electronic control apparatus 10 includes the first processor 11. The first processor 11 that controls the braking of the vehicle may be mounted on the first printed circuit board 120. The first processor 11 may provide the control signal for controlling the motor 40 and/or the valve 50 based on the pedal signal of the pedal sensor 30 to the first motor driving circuit 12 and/or the first valve driving circuit 13.

The first electronic control apparatus 10 includes the first driving circuit 12. A plurality of switching elements implementing the first motor driving circuit 12 may be mounted on the first printed circuit board 120. Each of the plurality of switching elements may include, for example, a metal oxide semiconductor field effect transistor (MOSFET), a bipolar junction transistor (BJT), or an insulated gate bipolar transistor (IGBT). The plurality of switching elements 340 may constitute, for example, an inverter circuit or an H-bridge circuit.

The first electronic control apparatus 10 includes the first valve driving circuit 13. An application-specific integrated circuit (ASIC) implementing the first valve driving circuit 13 may be mounted on the first printed circuit board 120. The application-specific integrated circuit may be provided with the plurality of switching circuits that allow or block the valve driving current supplied to the plurality of valve coils 51.

As illustrated in FIGS. 6 and 7, the second electronic control apparatus 20 may include a second housing 210, a second printed circuit board 220, electrical and/or electronic components mounted thereon, and a cover 300.

The second housing 210 forms an appearance of the second electronic control apparatus 20 and may be made of a non-conductive material. The first housing 110 is provided on the second housing 210, and the second housing 210 may overlap at least a portion of the first housing 110.

The second housing 210 may protect the second printed circuit board 220 and the electrical/electronic components mounted thereon from the outside. In particular, the second housing 210 may seal its internal space from the outside together with the cover 300, thereby blocking external foreign substances such as moisture from flowing into the inside.

A second accommodating space accommodating the second printed circuit board 220 is formed on one surface of the second housing 210, and one side of the second accommodating space may be open. One open side of the second accommodating space may be closed by the cover 300.

The first electronic control apparatus 10 may be provided outside the second accommodating space formed in the second housing 210.

A second valve pin 231 may be provided in the second housing 210. The second valve pin 231 may penetrate through the second housing 210 to extend from the first accommodating space of the first housing 110 to the second accommodating space of the second housing 210. In this case, the second valve pin 231 may be provided integrally with the second housing 210. For example, the second valve pin 231 may be fixed to the second housing 210 through the insert molding method.

One end of the second valve pin 231 on the first accommodating space may be inserted into a conductive connection member 400. The conductive connection member 400 has a hollow into which the second valve pin 231 may be inserted and may be made of an elastic conductive material. For example, the conductive connection member 400 may include a cylindrical spring or a zigzag-shaped leaf spring.

In addition, the first valve pin 131 of the plurality of valve coils 51 described above may also be inserted into the hollow of the conductive connection member 400.

In this way, one end of the second valve pin 231 may be electrically connected to the first valve pin 131 through the conductive connection member 400. In this way, the second valve pin 231 may be electrically connected to a valve coil 51.

The other end of the second valve pin 231 on the second accommodating space may be electrically connected to the second electronic control apparatus 20. In this way, the plurality of valve coils 51 may be electrically connected to the first electronic control apparatus 10 through the first valve pin 131, and electrically connected to the second electronic control apparatus 20 through the first valve pin 131, the conductive connection member 400, and the second valve pin 231.

The second housing 210 may be provided with a second pedal sensor pin 232. The second pedal sensor pin 232 may penetrate through the second housing 210 to extend from the first accommodating space of the first housing 110 to the second accommodating space of the second housing 210. In this case, the second pedal sensor pin 232 may be provided integrally with the second housing 210. For example, the second pedal sensor pin 232 may be fixed to the second housing 210 through the insert molding method.

One end of the second pedal sensor pin 232 on the first accommodating space may be inserted into a hollow of the conductive connection member 400. In addition, the first pedal sensor pin 132 described above may also be inserted into the hollow of the conductive connection member 400. In this way, one end of the second pedal sensor pin 232 may be electrically connected to the first pedal sensor pin 132 through the conductive connection member 400. In this way, the second pedal sensor pin 232 may be electrically connected to the pedal sensor 30.

The other end of the second pedal sensor pin 232 on the second accommodating space may be electrically connected to the second electronic control apparatus 20. In this way, the pedal sensor 30 may be electrically connected to the first electronic control apparatus 10 through the first pedal sensor pin 132, and may be electrically connected to the second electronic control apparatus 20 through the first pedal sensor pin 132, the conductive connection member 400, and the second pedal sensor pin 232.

The second housing 210 may be provided with a second power pin 233, a second ground pin 234, and a second communication pin 235. The second power pin 233, the second ground pin 234, and the second communication pin 235 each penetrate through the second housing 210 to extend from the first accommodating space of the first housing 110 to the second accommodating space of the second housing 210. In this case, the second housing 210 may be integrally provided with the second power pin 233, the second ground pin 234, and the second communication pin 235. For example, the second power pin 233, the second ground pin 234, and the second communication pin 235 may be fixed to the second housing 210 through the insert molding method.

One end of each of the second power pin 233, the second ground pin 234, and the second communication pin 235 on the first accommodating space may be inserted into the hollow of the conductive connection member 400. In addition, the above-described first power pin 133, first ground pin 134, and first communication pin 135 may also be inserted into the hollow of the conductive connection member 400. In this way, one ends of the second power pin 233, the second ground pin 234, and the second communication pin 235 may be electrically connected to the first power pin 133, the first ground pin 134, and the first communication pin 135, respectively through the conductive connection member 400. In this way, the second power pin 233 and the second ground pin 234 may be electrically connected to an external power supply, and the second communication pin 235 may also be communicatively connected to an external device.

The other end of each of the second power pin 233, the second ground pin 234, and the second communication pin 235 on the second accommodating space may be electrically connected to the second electronic control apparatus 20. In this way, the second electronic control apparatus 20 may be electrically connected to an external power supply through the second power pin 233 and the second ground pin 234, and may be communicatively connected to an external device through the second communication pin 235.

The second housing 210 may be provided with a plurality of second motor pins 236. Each of the plurality of second motor pins 236 may penetrate through the second housing 210 to extend from the first accommodating space of the first housing 110 to the second accommodating space of the second housing 210. The plurality of second motor pins 236 may be provided integrally with the second housing 210. For example, the plurality of second motor pins 236 may be fixed to the second housing 210 through the insert molding method.

One end of each of the plurality of second motor pins 236 on the first accommodating space may be inserted into the hollow of the conductive connection member 400. In addition, the plurality of second motor pins 236 described above may also be inserted into the hollow of the conductive connection member 400. In this way, one end of the plurality of second motor pins 236 may be electrically connected to each of the plurality of first motor pins 136 through the conductive connection member 400. In this way, the plurality of second motor pins 236 may receive power from an external power supply.

The other end of each of the plurality of second motor pins 236 on the second accommodating space may be electrically connected to the second electronic control apparatus 20. In this way, the second electronic control 20 may be apparatus electrically connected to the motor 40 through a plurality of second motor pins 236.

The second electronic control apparatus 20 may further include the second printed circuit board 220 provided in the second accommodating space of the second housing 210, and electrical and/or electronic components mounted on the second printed circuit board 220 to implement the functions of the second electronic control apparatus 20.

The second pedal sensor pin 232, the second power pin 233, the second ground pin 234, the second communication pin 235, the plurality of second motor pins 236, and the second valve pin 231 fixed to the second housing 210 may be inserted into the second printed circuit board 220.

A plurality of second through holes 221 into which the second pedal sensor pin 232, the second power pin 233, the second ground pin 234, the second communication pin 235, the plurality of second motor pins 236 and/or second valve pins 231 are inserted may be formed on the second printed circuit board 220. In addition, the second printed circuit board 220 may be electrically connected to the second pedal sensor pin 232, the second power pin 233, the second ground pin 234, the second communication pin 235, and the plurality of second motor pins 236 and/or second valve pins 231.

The second power circuit 24, the second processor 21, the second motor driving circuit 22, and the second valve driving circuit 23 may be mounted on the second printed circuit board 220. The second power circuit 24, the second processor 21, the second motor driving circuit 22, and the second valve driving circuit 23 may be the same as the first power circuit 14, the first processor 11, the first motor driving circuit 12, and the first valve driving circuit 13 mounted on the first printed circuit board 120.

The cover 300 may seal the accommodating of the housing 100 in which the first printed circuit board 120 and the second printed circuit board 220 are accommodated. For example, based on FIGS. 5 and 6, the accommodating space may be provided at a lower portion of the housing 100, and the cover 300 may be provided at a lower side of the housing 100 to close the accommodating space that is open downward.

The cover 300 is hook-coupled to the housing 100, but is not limited thereto. For example, the cover 300 may be coupled to the housing 100 through a screw, or the cover 300 may be fitted into the housing 100.

The first power pin 133, the first ground pin 134, and the first communication pin 135 may be electrically connected to the first printed circuit board 120 of the first electronic control apparatus 10, and may also be electrically connected to the second power pin 233, the second ground pin 234, and the second communication pin 235 through the conductive connection member 400. The second power pin 233, the second ground pin 234, and the second communication pin 235 may be electrically connected to the second printed circuit board 220 of the second electronic control apparatus 20. In this way, the external power supply connected to the first power pin 133 and the first ground pin 134 may provide power to the first electronic control apparatus 10 and the second electronic control apparatus 20, and an external device connected to the first communication pin 135 may communicate with the first electronic control apparatus 10 and the second electronic control apparatus 20.

The first pedal sensor pin 132 may be electrically connected to the first printed circuit board 120 of the first electronic control apparatus 10, and may also be electrically connected to the second pedal sensor pin 232 through the conductive connection member 400. The second pedal sensor pin 232 may be electrically connected to the second printed circuit board 220 of the second electronic control apparatus 20. In this way, the pedal sensor 30 connected to the first pedal sensor pin 132 may provide a pedal signal to the first electronic control apparatus 10 and the second electronic control apparatus 20.

The first motor pin 136 connected to the motor connector 150 may be electrically connected to the first printed circuit board 120 of the first electronic control apparatus 10, and may also be electrically connected to the second motor pin 136 through the conductive connection member 400. The second motor pin 236 may be electrically connected to the second printed circuit board 220 of the second electronic control apparatus 20. In this way, at least one of the first electronic control apparatus 10 and the second electronic control apparatus 20 may provide a motor driving current to the motor 40 through the motor connector 150 connected to the first motor pin 136.

The first valve pin 131 of the plurality of valve coils 51 may be electrically connected to the first printed circuit board 120 of the first electronic control apparatus 10, and may also be electrically connected to the second valve pin 231 through the conductive connection member 400. The second valve pin 231 may be electrically connected to the second printed circuit board 220 of the second electronic control apparatus 20. In this way, at least one of the first electronic control apparatus 10 and the second electronic control apparatus 20 may provide the valve driving current to the plurality of valve coils 51 through the first valve pin 131.

As described above, the first electronic control apparatus 10 including the first printed circuit board 120 may be sealed by the first housing 110 and the second housing 210, and the second electronic control apparatus 20 including the second printed circuit board 220 may be sealed by the second housing 210 and the cover 300.

The first electronic control apparatus 10 may be electrically connected to the external power supply, the external device, the pedal sensor 30, the motor 40, and the valve 50 through the first pin(s) 132 to 136 and the first valve pin 131 insert-molded into the first housing 110. In addition, the second electronic control apparatus 20 may be electrically connected to the external power supply, the external device, the pedal sensor 30, the motor 40, the valve 50, and the first electronic control apparatus 10 through the second pin(s) 231 to 236 insert-molded in the second housing 210 and the conductive connection member 400. In this case, the conductive connection member 400 may be made of an elastic conductive material.

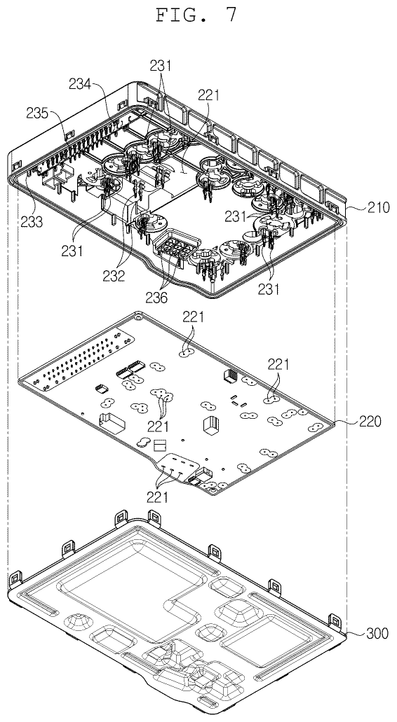

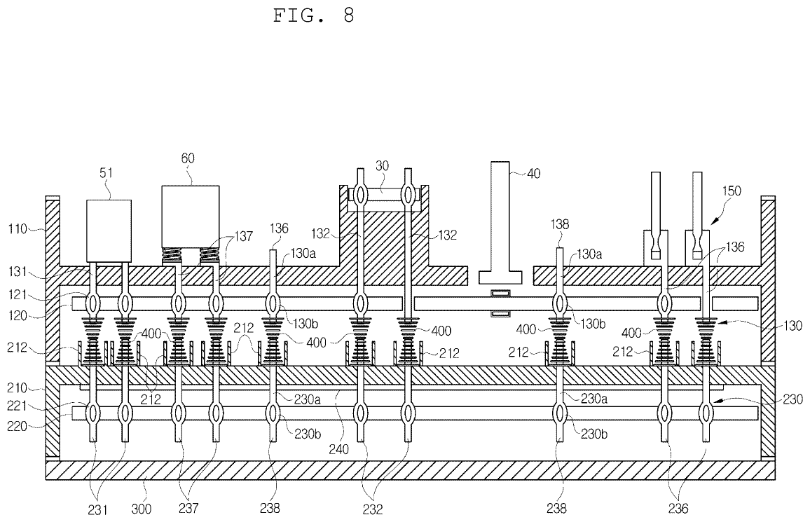

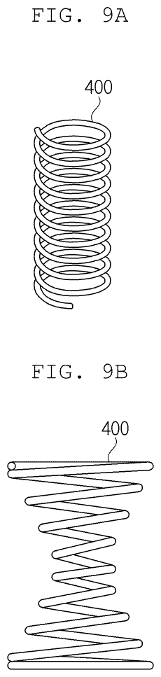

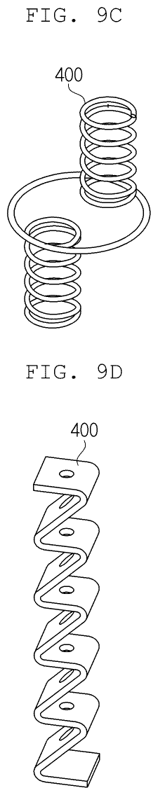

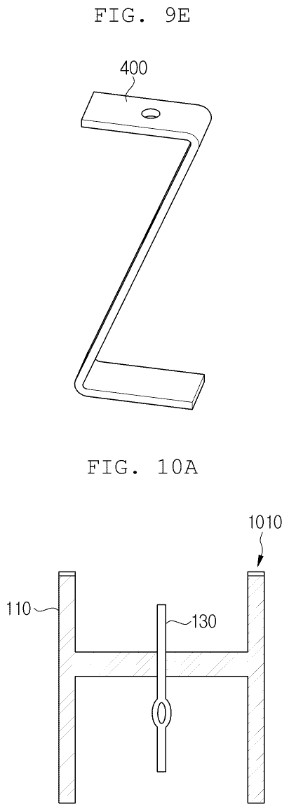

FIG. 8 is a diagram illustrating side cross-sections of the first and second electronic control apparatuses according to an exemplary embodiment. FIGS. 9A, 9B, 9C, 9D, and 9E are diagrams illustrating an example of a conductive connection member connecting the first electronic control apparatus and the second electronic control apparatus according to an exemplary embodiment.

As illustrated in FIG. 8, the brake apparatus 1 may include the valve coil 51, the pressure sensor 60, the pedal sensor 30, the motor 40, the first electronic control apparatus 10, and the second electronic control apparatus 20.

The pressure sensor 60 is provided in a hydraulic pressure control unit (HCU) constituting the brake apparatus 1. The pressure sensor 60 may be electrically connected to the first and second electronic control apparatuses 10 and 20 when the hydraulic pressure control device is assembled to the first and second electronic control apparatuses 10 and 20.

The valve coil 51 may include the first valve pin 131 connected to the first electronic control apparatus 10.

The first electronic control apparatus 10 may include the first housing 110, the first pin(s) 130 fixed to the first housing 110, and the first printed circuit board 120 into which the first pin(s) 130 is inserted.

The first pin(s) 130 may include a first pressure sensor pin 137, a first internal pin 138, a first pedal sensor pin 132, a first motor pin 136, etc. The first pressure sensor pin 137 may be fixed to the first housing 110, and electrically connected to the pressure sensor 60 when the hydraulic pressure control device is assembled to the first and second electronic control apparatuses 10 and 20. The first pedal sensor pin 132 may be fixed to the first housing 110 and electrically connected to the pedal sensor 30. The first motor pin 136 may be fixed to the first housing 110 and electrically connected to the motor connector 150.

The first pin(s) 130 may protrude to the first accommodating space from the first housing 110. The first pin(s) 130 protruding to the first accommodating space may be coupled to the first printed circuit board 120.

Each of the first pin(s) 130 may include a first pin body 130a and a first pin head 130b. The first pin head 130b may be thicker than the first pin body 130a. For example, a cross-sectional area of the first pin head 130b may be larger than that of the first pin body 130a.

The first pin body 130a may be fixed to the first housing 110 by the insert molding method.

The first pin head 130b may be inserted into the first printed circuit board 120. The plurality of first through holes 121 is formed on the first printed circuit board 120, and the first pin heads 130b of each of the first pin(s) 130 may be inserted into the plurality of first through holes 121 of the first printed circuit board 120. In this way, the first printed circuit board 120 may be fixed to the first housing 110 by the first pin(s) 130.

The inner surfaces of the plurality of first through holes 121 may be coated with a conductive material. Therefore, when the first pin heads 130b of each of the first pin(s) 130 are inserted into the plurality of first through holes 121, each of the first pin(s) 130 may be electrically connected to the first printed circuit board 120. For example, the first pressure sensor pin 137, the first internal pin 138, and the first pedal sensor pin 132 may be electrically connected to the first processor 11 mounted on the first printed circuit board 120. The first motor pin 136 may be electrically connected to the first motor driving circuit 12, and the first valve pin 131 may be electrically connected to the second valve driving circuit 23.

Furthermore, the first processor 11, the first motor driving circuit 12, the first valve driving circuit 13, and the first power circuit 14 mounted on the first printed circuit board 120 may each be electrically connected to the pedal sensor 30, the pressure sensor 60, the motor 40, the valve 50, and the external power supply through the first pin(s) 130.

The second electronic control apparatus 20 may include the second housing 210, the second pin(s) 230 fixed to the second housing 210, the second printed circuit board 220 into which the second pin(s) 230 is inserted, the potting member 240, and the cover 300.

The second pin(s) 230 may include a second pressure sensor pin 237, a second internal pin 238, a second pedal sensor pin 232, a second motor pin 236, a second valve pin 231, etc. The second pressure sensor pin 237, the second internal pin 238, the second pedal sensor pin 232, the second motor pin 236, and the second valve pin 231 may each be fixed to the second housing 210. The second pressure sensor pin 237, the second internal pin 238, the second pedal sensor pin 232, the second motor pin 236, and the second valve pin 231 may be electrically connected to the first pressure sensor pin 137, the first internal pin 138, the first pedal sensor pin 132, the first motor pin 136, and the first valve pin 131, respectively, through the connection member 400 when the second electronic control apparatus 20 is assembled to the first electronic control apparatus 10.

The second pin(s) 230 may protrude to the second accommodating space from the second housing 210. The second pin(s) 230 protruding to the second accommodating space may be coupled to the second printed circuit board 220.

Each of the second pin(s) 230 may include a second pin body 230a and a second pin head 230b. The second pin head 230b may be thicker than the second pin body 230a. For example, a cross-sectional area of the second pin head 230b may be larger than that of the first pin body 130a.

The second pin body 230a may be fixed to the second housing 210 by the insert molding method.

The second pin head 230b may be inserted into the second printed circuit board 220. The plurality of second through holes 221 are formed on the second printed circuit board 220, and the second pin heads 230b of each of the second pin(s) 230 may be inserted into the plurality of second through holes 221 of the second printed circuit board 220. In this way, the second printed circuit board 220 may be fixed to the second housing 210 by the second pin(s) 230.

The inner surfaces of the plurality of second through holes 221 may be coated with a conductive material. In this way, when the second pin heads 230b of each of the second pin(s) 230 are inserted into the plurality of second through holes 221, each of the second pin(s) 230 may be electrically connected to the second printed circuit board 220. For example, the second pressure sensor pin 237, the second internal pin 238, and the second pedal sensor pin 232 may be electrically connected to the second processor 21 mounted on the second printed circuit board 220. The second motor pin 236 may be electrically connected to the second motor driving circuit 22, and the second valve pin 231 may be electrically connected to the second valve driving circuit 23.

Furthermore, the second processor 21, the second motor driving circuit 22, the second valve driving circuit 23, and the second power circuit 24 mounted on the second printed circuit board 220 may each be electrically connected to the pedal sensor 30, the pressure sensor 60, the motor 40, the valve 50, and the external power supply through the first pin(s) 130 and the second pin(s) 230.

The second pin(s) 230 and the plurality of second through holes 221 may be surrounded by the potting member 240.

The second pin(s) 230 made of metal and the second housing 210 made of plastic may not be coupled to each other, and there is a gap between the insert-molded second pin(s) 230 and the second housing 210. Moisture may flow into the second accommodating space, in which the second printed circuit board 220 is accommodated, through the gap.

The potting member 240 may be provided to prevent the inflow of moisture.

The potting member 240 surrounds the second pin(s) 230 that have passed through the plurality of second through holes 221, and may seal the gap between the plurality of second through holes 221 and the second pin(s) 230. In this way, the inflow of moisture through the gap between the plurality of second through holes 221 and the second pin(s) 230 may be blocked. The potting member 240 may be made of various types of materials such as resin, epoxy, and adhesive.

Due to the potting member 240, the inflow of moisture into the second accommodating space may be blocked.

On the other hand, the inflow of moisture into the first accommodating space is not blocked. An insertion hole into which the plurality of valve coils 51 is inserted and the hollow into which the motor 40 of the hydraulic pressure control device is inserted may be formed, and moisture may flow into the first housing 110 through the insertion hole and the hollow.

When moisture flows into the first housing 110, the first printed circuit board 120 and the electrical and/or electronic components mounted thereon may malfunction or be damaged. Even if moisture flows into the first housing 110, the potting member 240 may prevent moisture from flowing into the second housing 210.

In this way, even if the fail occurs in the first electronic control apparatus 10 including the first printed circuit board 120 and the electrical components and/or electronic components mounted thereon due to the inflow of moisture, the second electronic control apparatus 20 accommodated inside the second housing 210 may still operate normally. In this way, the second electronic control apparatus 20 may control the hydraulic pressure control device, that is, the valve 50 and the motor 40, in response to the fail of the first electronic control apparatus 10.

In other words, since the inflow of moisture into the second housing 210 is blocked, the second electronic control apparatus 20 may provide redundancy to the first electronic control apparatus 10.

As described above, the second pin(s) 230 may be connected to each of the first pin(s) 130 through the conductive connection member 400.

The second housing 210 may be provided with a coupling guide 212 for guiding the coupling between the first pin(s) 130 and the second pin(s) 230 through the conductive connection member 400. For example, the conductive connection member 400 may be seated on the coupling guide 212.

For example, the coupling guide 212 may be formed integrally with the second housing 210 and may restrict movement of the conductive connection member 400. In this way, the first pin(s) 130 may be easily inserted into the hollow of the conductive connection member 400.

The conductive connection member 400 may be made of a conductive material, such as metal, and may have elasticity. The conductive connection member 400 may include, for example, a spring having a hollow.

As illustrated in FIG. 9A, the conductive connection member 400 may include a cylindrical spring made of metal or coated with metal. However, the shape of the conductive connection member 400 is not limited to that illustrated in FIG. 9A.

For example, the conductive connection member 400 may include an hourglass-shaped spring as illustrated in FIG. 9B. By using the hourglass-shaped spring, the first pin(s) 130 and the second pin(s) 230 may be easily inserted into the hollow of the conductive connection member 400, and a contact area between the first pin(s) 130 and the second pin(s) 230, and the conductive connection member 400 may also increase.

As another example, the conductive connection member 400 may include a spring (hereinafter referred to as an ‘offset spring’) whose upper and lower centers are misaligned as illustrated in FIG. 9C. The offset spring may offset a difference between the position of the first pin(s) 130 and the position of the second pin(s) 230. For example, a deviation may occur between the positions of the first pin(s) 130 and the positions of the second pin(s) 230 due to difficulties in the design of the printed circuit board or the design of the hydraulic pressure control device. The offset spring may offset the difference between the positions of the first pin(s) 130 and the positions of the second pin(s) 230.

As another example, the conductive connection member 400 may include a zigzag-shaped leaf spring as illustrated in FIGS. 9D and 9E. The holes through which the first pin(s) 130 and the second pin(s) 230 may pass may be formed in the center of the zigzag-shaped leaf spring.

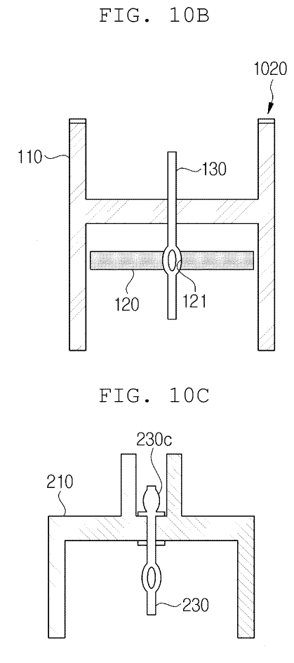

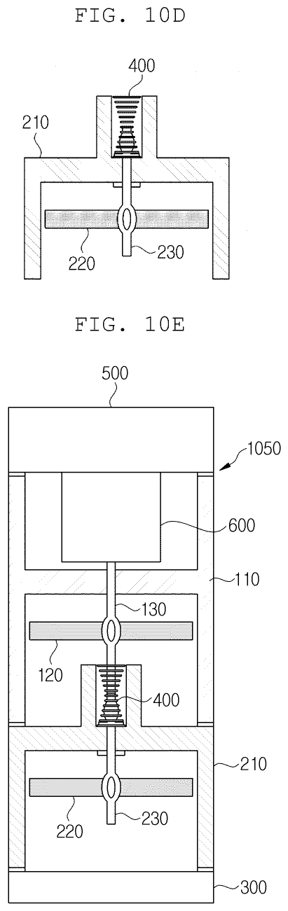

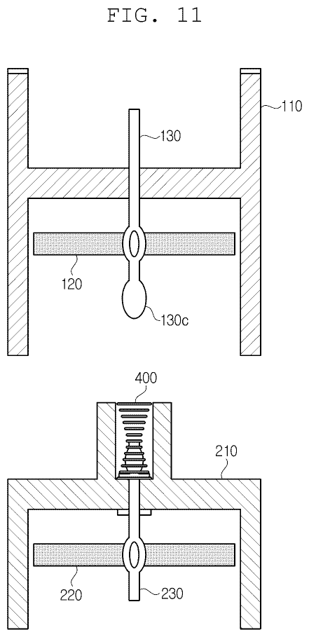

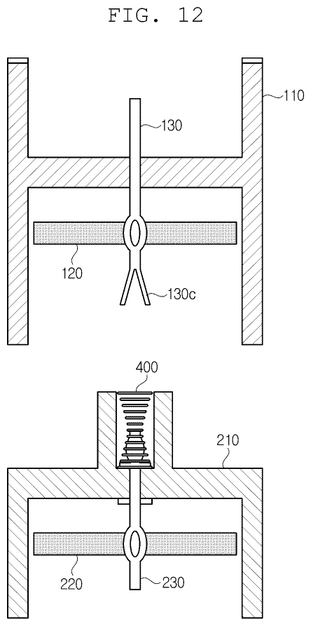

FIGS. 10A-10E are diagrams schematically illustrating examples of assembling the electronic control apparatus according to an exemplary embodiment.

As illustrated in FIG. 10A, the first pin(s) 130 may be fixed to the first housing 110 by the insert molding.

As illustrated in FIG. 10B, the first printed circuit board 120 may be assembled to the first pin(s) 130 and the first housing 110. By assembling the first printed circuit board 120 with the first pin(s) 130 and the first housing 110, the first electronic control apparatus 10 may be provided.

The first pin(s) 130 may be inserted into the plurality of first through the holes 121 of the first printed circuit board 120. The first pin(s) 130 may be made of a conductive material, and the conductive material may be applied to the inner surfaces of the plurality of first through holes 121. In this way, the first pin(s) 130 may be electrically connected to the first printed circuit board 120.

As illustrated in FIG. 10C, the second pin(s) 230 may be fixed to the second housing 210 by the insert molding.

As illustrated in FIG. 10D, the second printed circuit board 220 and the conductive connection member 400 may be assembled to the second pin(s) 230 and the second housing 210. By assembling the first printed circuit board 220 with the second pin(s) 230 and the second housing 210, the second electronic control apparatus 20 may be provided.

The second pin(s) 230 may be inserted into the plurality of second through holes 221 of the second printed circuit board 220. The second pin(s) 230 may be made of a conductive material, and the conductive material may be applied to the inner surfaces of the plurality of second through holes 221. In this way, the second pin(s) 230 may be electrically connected to the second printed circuit board 220.

In addition, the second pin(s) 230 may be inserted into the hollow of the conductive connection member 400. A second connection head 230c may be provided on the second pin(s) 230 so that the second pin(s) 230 may be stably fixed to the conductive connection member 400. The second connection head 230c may be located on the opposite side of the second pin head 230b inserted into the second printed circuit board 220 and may be inserted into the hollow of the conductive connection member 400.

As illustrated in FIG. 10E, a hydraulic pressure control unit 500, an electrical/electronic component 600, the first electronic control apparatus 10, the second electronic control apparatus 20, and the cover 300 may be assembled.

The hydraulic pressure control unit 500 includes, for example, the motor 40 and the cylinder-piston that generate the hydraulic pressure, the flow path that guides the hydraulic pressure to the wheel cylinder, and the valve 50 that is provided on the flow path to open or close the flow path.

The electrical/electronic component 600 may include the electrical and/or electronic components provided in the hydraulic pressure control unit 500 or the electronic control unit. For example, it may include the pedal sensor 30, the motor connector 150, the valve coil 51, the pressure sensor 60, and/or the power connector 140, etc.

By assembling the hydraulic pressure control unit 500 and the first electronic control unit 10, the electrical/electronic component 600 may be electrically connected to the first pin(s) 130 of the first electronic control apparatus 10.

The first pin(s) 130 of the first electronic control apparatus 10 may be electrically connected to the first printed circuit board 120. In addition, as the first electronic control unit 10 and the second electronic control unit 20 are assembled, the first pin(s) 130 of the first electronic control apparatus 10 may be electrically connected to the second pin(s) 230 through the conductive connection member 400.

The second pin(s) 230 of the second electronic control apparatus 20 may be electrically connected to the second printed circuit board 220.

As described above, the first pin(s) 130 may be electrically connected to the second pin(s) 230 through the conductive connection member 400. The first pin(s) 130, the second pin(s) 230, and the conductive connection member 400 may have various shapes so that they can be easily and stably connected to each other.

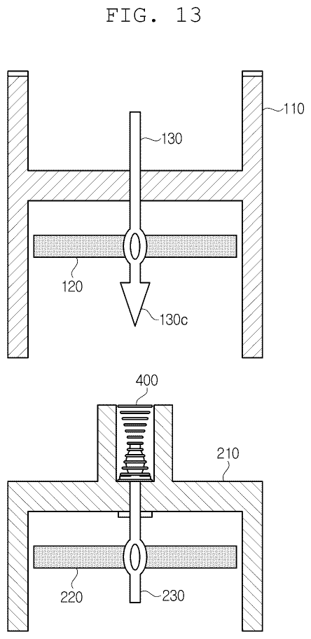

FIG. 11 is a diagram illustrating an example of the first pin, the second pin, and the conductive connection member of the electronic control apparatus according to an exemplary embodiment.

As illustrated in FIG. 11, the second pin(s) 230 fixed to the second housing 210 may include the second connection head 230c in the shape of a rugby ball. By the rugby ball-shaped second connection head 230c, the second pin(s) 230 may stably fix the conductive connection member 400 and increase a contact surface with the conductive connection member 400.

The first pin(s) 130 fixed to the first housing 110 may also include the rugby ball-shaped first connection head 130c. By the rugby ball-shaped first connection head 230c, the first pin(s) 130 may stably fix the conductive connection member 400 and increase the contact surface with the conductive connection member 400.

FIG. 12 is a diagram illustrating an example of the first pin, the second pin, and the conductive connection member of the electronic control apparatus according to an exemplary embodiment.

As illustrated in FIG. 12, the first pin(s) 130 fixed to the first housing 110 may include the first connection head 130c in the shape of a fork with split ends. When the first pin(s) 130 is inserted into the conductive connection member 400, the fork-shaped first connection head 130c is caught on the conductive connection member 400, so the first pin(s) 130 may stably be fixed to the conductive connection member 400 and the contact surface between the first pin(s) 130 and the conductive connection member 400 may increase.

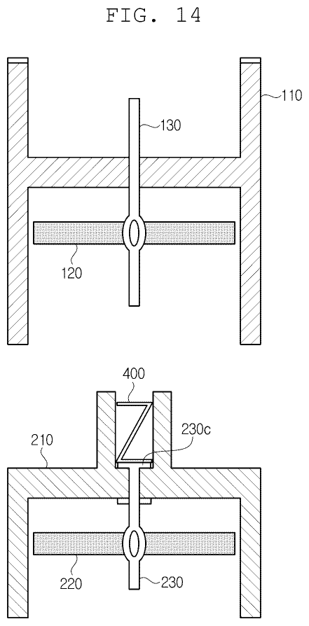

FIG. 13 is a diagram illustrating an example of the first pin, the second pin, and the conductive connection member of the electronic control apparatus according to an exemplary embodiment.

As illustrated in FIG. 13, the first pin(s) 130 fixed to the first housing 110 may include the arrowhead-shaped first connection head 130c. The arrowhead-shaped first connection head 130c may allow the first pin(s) 130 to be easily inserted into the conductive connection member 400. In addition, when the first pin(s) 130 is inserted into the conductive connection member 400, the arrowhead-shaped first connection head 130c is caught on the conductive connection member 400, so the first pin(s) 130 may stably be fixed to the conductive connection member 400 and the contact surface between the first pin(s) 130 and the conductive connection member 400 may increase.

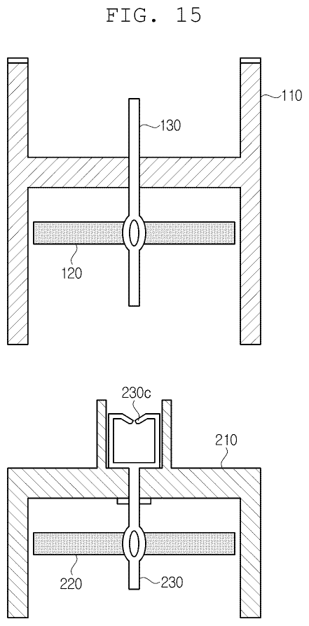

FIG. 14 is a diagram illustrating an example of the first pin, the second pin, and the conductive connection member of the electronic control apparatus according to an exemplary embodiment.

As illustrated in FIG. 14, the conductive connection member 400 may include a zigzag-shaped leaf spring in which holes are formed.

The second pin(s) 230 fixed to the second housing 210 may include the plate-shaped second connection head 230c. The plate-shaped second connection head 230c may stably contact the zigzag-shaped leaf spring.

The first pin(s) 130 fixed to the first housing 110 may be inserted into the hole in the center of the zigzag-shaped leaf spring.

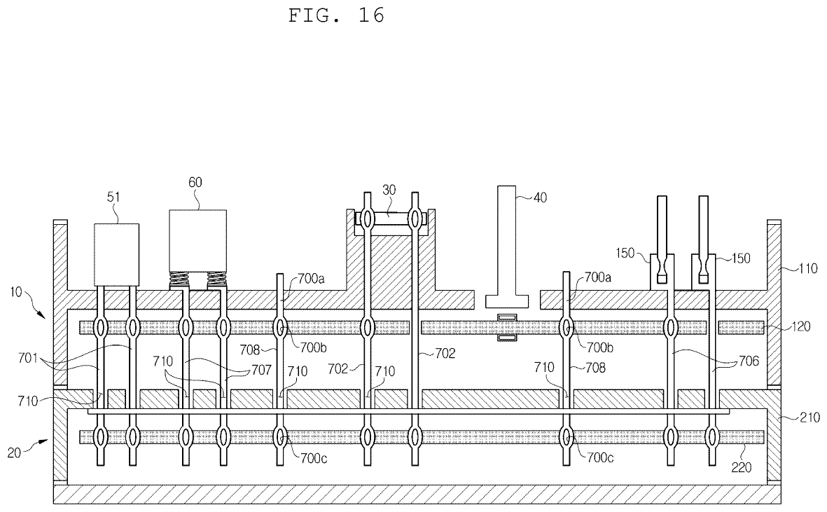

FIG. 15 is a diagram illustrating an example of the first pin and the second pin of the electronic control apparatus according to an exemplary embodiment.

As illustrated in FIG. 15, the second pin(s) 230 fixed to the second housing 210 may include the second connection head 230c in the shape of a female connector. In addition, the first pin(s) 130 fixed to the first housing 110 may include a first connection head 130c in the shape of a male connector.

In this way, the first pin(s) 130 and the second pin(s) 230 may be electrically connected to each other by the first connection head 130c in the shape of the male connector and the second connection head 230c in the shape of a female connector without the conductive connection member.

FIG. 16 is a diagram conceptually illustrating the first and the second electronic control apparatuses according to an exemplary embodiment.

As illustrated in FIG. 16, the brake apparatus 1 may include the valve coil 51, the pressure sensor 60, the pedal sensor 30, the motor 40, the first electronic control apparatus 10, and the second electronic control apparatus 20.

The valve coil 51 may include the valve pin 701 connected to the first electronic control apparatus 10.

The first electronic control apparatus 10 may include the first housing 110, a fixing pin(s) 700 fixed to the first housing 110, and the first printed circuit board 120 into which the fixing pin(s) 700 is inserted.

The fixing pin(s) 700 may include a pressure sensor pin 707, an internal pin 708, a pedal sensor pin 702, a motor pin 706, etc. The pressure sensor pin 707 may be fixed to the first housing 110, and electrically connected to the pressure sensor 60 when the hydraulic pressure control device is assembled to the first and second electronic control apparatuses 10 and 20. The pedal sensor pin 702 may be fixed to the first housing 110 and electrically connected to the pedal sensor 30. The motor pin 706 may be fixed to the first housing 110 and electrically connected to the motor connector 150.

The fixing pin(s) 700 may be fixed to the first housing 110 by the insert molding method.

The fixing pin(s) 700 may be inserted into the first printed circuit board 120. The fixing pin(s) may include a pin body 700a, a first pin head 700b, and a second pin head 700c. The first pin head 700b may be thicker than the pin body 700a. For example, the cross-sectional area of the first pin head 700b may be larger than that of the pin body 700a. In this way, the first printed circuit board 120 may be electrically connected to the fixing pin(s) 700 and fixed to the first housing 110.

The second electronic control apparatus 20 may include the second housing 210, the second printed circuit board 220, the potting member 240, and the cover 300.

The fixing pin(s) 700 may pass through the second housing 210. The second housing 210 may be provided with housing hole(s) 710 through which the fixing pin(s) may pass. The diameter of the housing hole(s) 710 may be larger than that of the second pin head 700c.

The fixing pin(s) 700 may be inserted into the second printed circuit board 220. The second pin head 700c may be thicker than the pin body 700a. For example, the cross-sectional area of the second pin head 700c may be larger than that of the pin body 700a. In this way, the second printed circuit board 220 may be electrically connected to the fixing pin(s) 700 and fixed to the first housing 110 and the second housing 210.

In addition, the potting member 240 may be provided to prevent the inflow of moisture. Due to the potting member 240, the inflow of moisture into the second housing 210 may be blocked.

According to one aspect of the present disclosure, it is possible to provide the electronic control apparatus for a vehicle that secures redundancy. As a result, it is possible to continuously control the vehicle even if the fail of the electronic control apparatus occurs.

An aspect of the present disclosure provides a brake apparatus for a vehicle that secures redundancy. As a result, it is possible to continuously control the brake of the vehicle even if the fail of the electronic control apparatus occurs.

Exemplary embodiments of the present disclosure have been described above. In the exemplary embodiments described above, some components may be implemented as a “module”. Here, the term ‘module’ means, but is not limited to, a software hardware component, such as a Field Programmable Gate Array (FPGA) or Application Specific Integrated Circuit (ASIC), which performs certain tasks. A module may advantageously be configured to reside on the addressable storage medium and configured to execute on one or more processors.

Thus, a module may include, by way of example, components, such as software components, object-oriented software components, class components and task components, processes, functions, attributes, procedures, subroutines, segments of program code, drivers, firmware, microcode, circuitry, data, databases, data structures, tables, arrays, and variables. The operations provided for in the components and modules may be combined into fewer components and modules or further separated into additional components and modules. In addition, the components and modules may be implemented such that they execute one or more CPUs in a device.

With that being said, and in addition to the above described exemplary embodiments, embodiments can thus be implemented through computer readable code/instructions in/on a medium, e.g., a computer readable medium, to control at least one processing element to implement any above described exemplary embodiment. The medium can correspond to any medium/media permitting the storing and/or transmission of the computer readable code.

The computer-readable code can be recorded on a medium or transmitted through the Internet. The medium may include Read Only Memory (ROM), Random Access Memory (RAM), Compact Disk-Read Only Memories (CD-ROMs), magnetic tapes, floppy disks, and optical recording medium. Also, the medium may be a non-transitory computer-readable medium. The media may also be a distributed network, so that the computer readable code is stored or transferred and executed in a distributed fashion. Still further, as only an example, the processing element could include at least one processor or at least one computer processor, and processing elements may be distributed and/or included in a single device.

While exemplary embodiments have been described with respect to a limited number of embodiments, those skilled in the art, having the benefit of this disclosure, will appreciate that other embodiments can be devised which do not depart from the scope as disclosed herein. Accordingly, the scope should be limited only by the attached claims.

What is claimed is:

1. An electronic control apparatus, comprising:
a first housing having a first accommodating space;
a second housing having a second accommodating space, which is separated from the first accommodating space;
a conductive first pin that penetrates through the first housing and is fixed to the first housing;
a conductive second pin that penetrates through the second housing and is fixed to the second housing;
a first printed circuit board positioned in the first accommodating space and configured to be electrically connected to the first pin, wherein the first printed circuit board has a first through hole into which the first pin is configured to be inserted;
a second printed circuit board positioned in the second accommodating space and configured to be electrically connected to the second pin, wherein the second printed circuit board has a second through hole into which the second pin is configured to be inserted; and
a conductive connection member configured to electrically connect the second pin with the first pin.

2. The electronic control apparatus of claim 1, wherein the first housing is positioned on the second housing, and
at least a portion of the first housing overlaps with a portion of the second housing.

3. The electronic control apparatus of claim 1, wherein the first pin is insert-molded into the first housing, and
the second pin is insert-molded into the second housing.

4. The electronic control apparatus of claim 1, wherein the first pin is protruded to the first accommodating space through the first housing and is connected to the first printed circuit board positioned in the first accommodating space, and
the second pin is protruded to the second accommodating space through the second housing and is connected to the second printed circuit board positioned in the second accommodating space.

5. The electronic control apparatus of claim 1, wherein the first pin comprises:
a first pin body fixed to the first housing; and
a first pin head provided on one side of the first pin body and inserted into the first through hole of the first printed circuit board, and
the second pin comprises:
a second pin body fixed to the second housing; and
a second pin head provided on one side of the second pin body and inserted into the second through hole of the second printed circuit board.

6. The electronic control apparatus of claim 5, wherein the first pin further comprises:
a first connection head provided at one end of the first pin body and in contact with the connection member, and
the second pin further comprises:
a second connection head provided at one end of the second pin body and in contact with the connection member.

7. The electronic control apparatus of claim 6, wherein the first connection head has at least one of a rugby ball shape, a fork shape, and an arrowhead shape.

8. The electronic control apparatus of claim 6, wherein the first connection head is positioned in the first accommodating space, and
the second connection head is positioned outside the second accommodating space.

9. The electronic control apparatus of claim 1, wherein the connection member comprises at least one of a cylindrical spring, an hourglass-shaped spring, an offset spring, and a zigzag-shaped leaf spring.

10. The electronic control apparatus of claim 1, further comprising:
a potting member configured to surround the second pin penetrating through the second housing.

11. The electronic control apparatus of claim 1, wherein the second housing comprises a coupling guide on which the connection member is seated.

12. The electronic control apparatus of claim 1, wherein the first pin is configured to be electrically connected to at least one of an external power supply, a pedal sensor, a motor, a valve, and a pressure sensor.

13. The electronic control apparatus of claim 1, further comprising:
a first processor mounted on the first printed circuit board, and
a second processor mounted on the second printed circuit board,
wherein the first processor is configured to be electrically connected to the second processor through the first pin, the connection member, and the second pin.

14. The electronic control apparatus of claim 13, wherein the first processor is configured to output a first control signal, and
the second processor is configured to output a second control signal, in response to a failure of the first processor.

15. A brake apparatus, comprising:
a pedal sensor;
a motor;
a valve;
a pressure sensor; and
an electronic control apparatus configured to control at least one of the motor and the valve based on an output of the pedal sensor and the pressure sensor,
wherein the electronic apparatus comprises:
a first housing having a first accommodating space;
a second housing having a second accommodating space, which is separated from the first accommodating space;
a plurality of first pins, which penetrate through the first housing, are fixed to the first housing, and are configured to be electrically connected to the pedal sensor, the motor, the valve, and the pressure sensor, respectively;
a plurality of second pins, which penetrate through the second housing and are fixed to the second housing;
a first printed circuit board positioned in the first accommodating space and configured to be electrically connected to the plurality of first pins, wherein the first printed circuit board has a plurality of first through holes into which the plurality of first pins are configured to be inserted,; and
a second printed circuit board positioned in the second accommodating space and configured to be electrically connected to the plurality of second pins, the second printed circuit board having a plurality of second through holes into which the plurality of second pins are configured to be inserted; and
a plurality of connection members configured to electrically connect the plurality of second pins with the plurality of first pins, respectively.

16. The brake apparatus of claim 15, wherein the first housing is on the second housing, and
at least a portion of the first housing overlaps with a portion of the second housing.

17. The brake apparatus of claim 15, wherein the plurality of first pins is insert-molded into the first housing, and
the plurality of second pins is insert-molded into the second housing.

18. An electronic control apparatus, comprising:
a first electronic control apparatus comprising:
a first housing comprising a plurality of first pins, which are protruded to a first accommodating space; and
a first printed circuit board positioned in the first accommodating space and configured to be electrically connected to the plurality of first pins;
a second electronic control apparatus comprising:
a second housing comprising a plurality of second pins, which are protruded to a second accommodating space; and
a second printed circuit board positioned in the second accommodating space and configured to be electrically connected to the plurality of second pins; and
a plurality of connection members configured to electrically connect the plurality of second pins with the plurality of first pins, respectively.

19. The electronic control apparatus of claim 18, wherein the first electronic control apparatus is positioned on the second electronic control apparatus, and
at least a portion of the first electronic control apparatus overlaps portion of the second electronic control apparatus.

20. The electronic control apparatus of claim 18, wherein each of the plurality of first pins is insert-molded into the first housing, and
each of the plurality of second pins is insert-molded into the second housing.
